(19) United States
(12) Patent Application Publication
(10) Pub. No.: US 2006/0121737 A1
(43) Pub. Date: Jun. 8, 2006

(54) Method of manufacturing a semiconductor device and method of manufacturing a thin layer using the same

(76) Inventors: Jae-Hyun Han, Gyeonggi-do (KR); Do-Hyoung Lee, Gyeonggi-do (KR); Seung-Ki Chae, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/291,287

(22) Filed: Nov. 30, 2005

(30) Foreign Application Priority Data
Dec. 2, 2004 (KR) 2004-100233

(51) Int. Cl. H01L 21/306; H01L 21/302; C23F 1/00; C25F 5/00

(52) U.S. Cl. 438/694; 134/1.1; 118/715; 156/345.1; 438/689

(57) ABSTRACT

A method includes providing a first distance between an inlet of a line and a chuck for supporting a substrate. A first material is applied to the substrate on the chuck through the line to process the substrate. A second distance is provided between the inlet of the line and the chuck. Byproducts generated during processing of the substrate are then removed using a second material. Here, the second material has reactivity with respect to the chuck having the second distance from the inlet smaller than that of the second material with respect to the chuck having the first distance from the inlet. A distance between the chuck and the inlet of the line is adequately adjusted in the process using the plasma gas so that the substrate on the chuck may not be moved.

### CROSS REFERENCE TO RELATED APPLICATIONS

This application claims priority to Korean Patent Application No. 10-2004-0100233, which was filed on 2 Dec. 2004. Korean Patent Application No. 10-2004-0100233 is incorporated by reference in its entirety for all purposes.

### BACKGROUND

1. Technical Field

This disclosure relates to methods of manufacturing semiconductor devices and thin layers using plasma.

2. Description of the Related Art

Generally speaking, a process of manufacturing a semiconductor device includes a deposition process for forming a thin layer on a semiconductor substrate and an etching process for patterning the thin layer to form a pattern. In particular, a plasma gas may be used to manufacture a semiconductor device having a design rule of no more than about 0.13 μm.

In a conventional method of manufacturing a semiconductor device using a plasma gas, a chamber is maintained under an atmosphere for performing a deposition process, an etching process, etc. A semiconductor substrate is placed on a chuck in the chamber. The deposition process and the etching process are performed on the semiconductor substrate on the chuck using the plasma gas. The semiconductor substrate is then unloaded from the chamber. A cleaning gas is introduced into the chamber to remove byproducts generated in the processes. A purge gas is introduced into the chamber to exhaust the byproducts and a remaining gas in the chamber from the chamber.

In the processes using the plasma gas, electrons having a high mobility collide against particles in the plasma gas so that the particles have electric charges. The particles having the electric charges are accelerated due to an electric potential difference between the plasma gas and the chuck. The accelerated particles collide against the semiconductor substrate, thereby performing the deposition process or the etching process.

However, since the semiconductor substrate is charged with the electric charges of the particles, the semiconductor substrate on the chuck is moved frequently and minutely in the processes. When the processes are carried out with the moving semiconductor substrate on the chuck, process errors occur. Furthermore, when the semiconductor substrate is excessively moved on the chuck, the semiconductor substrate is shaken when lifting the semiconductor substrate from the chuck so that the semiconductor substrate falls to a bottom face of the chamber.

As described above, the process errors due to the moving of the semiconductor substrate frequently occur in the conventional process using the plasma gas. As a result, the conventional method of manufacturing a semiconductor device has inferior reliability and low productivity.

An example of an apparatus or a method for suppressing the movement of a semiconductor substrate on a chuck is disclosed in Korean Patent Laid Open Publication No. 2001-36146, which teaches that the movement of the semiconductor substrate on the chuck may be suppressed using an electrical device. However, the presence of an additional electrical device adds additional cost and complexity to a processing chamber.

Embodiments of the invention address these and other disadvantages of the conventional art.

### SUMMARY

Embodiments of the invention include methods of manufacturing a semiconductor device and thin layers that are capable of suppressing movement of a semiconductor substrate on a chuck when a plasma gas is present.

### BRIEF DESCRIPTION OF THE DRAWINGS

The above and other features and advantages of the invention will become readily apparent by reference to the following detailed description when considered in conjunction with the accompanying drawings.

FIG. 1 is a sectional diagram illustrating an apparatus capable of performing a process using a plasma gas in accordance with some embodiments of the invention.

FIG. 2 is a sectional diagram illustrating the formation of a thin film on the chuck of the apparatus of FIG. 1 after a plasma gas is introduced within the apparatus, according to some embodiments of the invention.

FIG. 3 is a sectional diagram illustrating the positioning of a semiconductor substrate on the chuck of the apparatus of FIG. 1 after the thin film is formed.

FIG. 4 is a graph illustrating characteristics of fluorine in accordance with process conditions for removing byproducts in the process using the plasma gas;

FIG. 5 is a sectional diagram illustrating a method of removing byproducts under a first condition in accordance with some embodiments of the invention.

FIG. 6 is a sectional diagram illustrating a method of removing byproducts under a second condition in accordance with some embodiments of the invention.

FIG. 7 is a sectional diagram illustrating an apparatus capable of performing a process using a plasma gas in accordance with some other embodiments of the invention.

FIG. 8 is a sectional diagram illustrating an apparatus capable of performing a process using a plasma gas in accordance with some other embodiments of the invention.

FIGS. 9 and 10 are sectional diagrams illustrating conventional problems to be solved by the invention.

### DETAILED DESCRIPTION

The invention is described more fully below with reference to the accompanying drawings, in which embodiments of the invention are shown. The invention may, however, be embodied in many different forms and should not be construed as limited to the embodiments set forth herein. Rather, these embodiments are provided so that this disclosure will be thorough and complete, and will fully convey the teachings of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

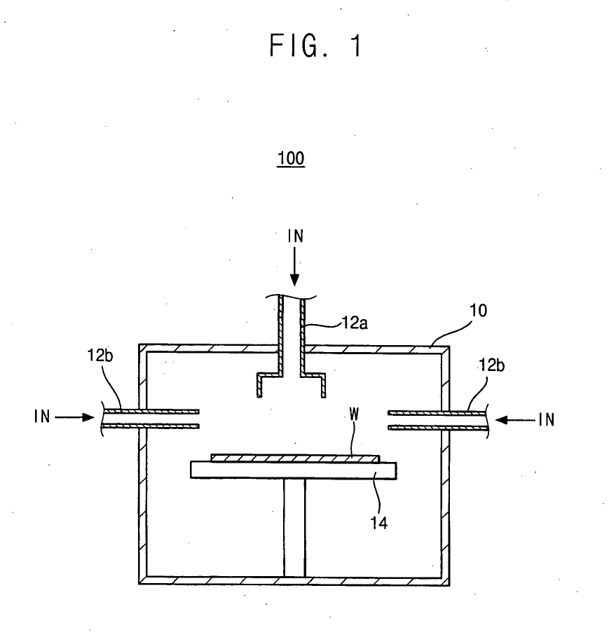

FIG. 1 is a sectional diagram illustrating an apparatus 100 capable of performing a process using a plasma gas in accordance with some embodiments of the invention.

Referring to FIG. 1, an apparatus 100 includes a chamber 10 and a chuck 14 disposed within the chamber 10. A semiconductor substrate W is positioned on the chuck 14. A plasma gas is generated in the chamber 10. Thus, first and second gas lines 12a and 12b for providing the chamber 10 with a gas are connected to the chamber 10. Furthermore, a source power line (not shown) and a bias power line (not shown) for ionizing the gas are connected to the chamber 10.

The first lines 12a are connected to an upper face of the chamber 10 in a vertical direction. The second gas lines 12b are connected to a side face of the chamber 10 in a horizontal direction. Thus, the gas downwardly flows in the chamber 10 through the gas lines 12a and 12b. In the present embodiment, the first and second gas lines 12a and 12b include a nozzle type structure. Alternatively, the first and second gas lines 12a and 12b may include a showerhead type structure that is capable of uniformly distributing the gas on the semiconductor substrate W. The source power line may be connected to the first gas line 12a or the second gas lines 12b. The bias power line is connected to the chuck 14.

In the illustrated embodiments, the apparatus 100 includes a capacitive coupled plasma (CCP) type plasma source. Thus, the first gas line 12a corresponds to an upper electrode and the chuck 14 corresponds to a lower electrode. Furthermore, the chuck 14 may include an electrostatic chuck (ESC) for holding the semiconductor substrate W with a Coulomb force. Thus, a direct current line (not shown) for generating the Coulomb force is connected to the ESC.

The gas is introduced into the chamber 10 through the first and second gas lines 12a and 12b. Furthermore, the source power and the bias power are applied to the chamber 10 through the source power line and the bias power line, respectively, to generate the plasma gas.

In the illustrated embodiments, a plasma gas is generated in the chamber 10. Alternatively, a plasma gas may be generated outside of the chamber 10 and subsequently introduced into the chamber 10.

Furthermore, an exhaust line (not shown) for exhausting a remaining plasma gas and byproducts may be connected to the chamber 10.

When a deposition gas is introduced into the chamber 10, the apparatus 100 is used as a deposition apparatus. When an etching gas is introduced into the chamber 10, the apparatus 100 is used as an etching apparatus. For example, to form a plasma enhanced oxide layer on the semiconductor substrate W, a SiH₄ gas is introduced into the chamber 10. To etch the plasma enhanced oxide layer, a CF₄ gas is introduced into the chamber 10.

A method of manufacturing a semiconductor device in accordance with some embodiments of the invention using the apparatus 100 is described in further detail below.

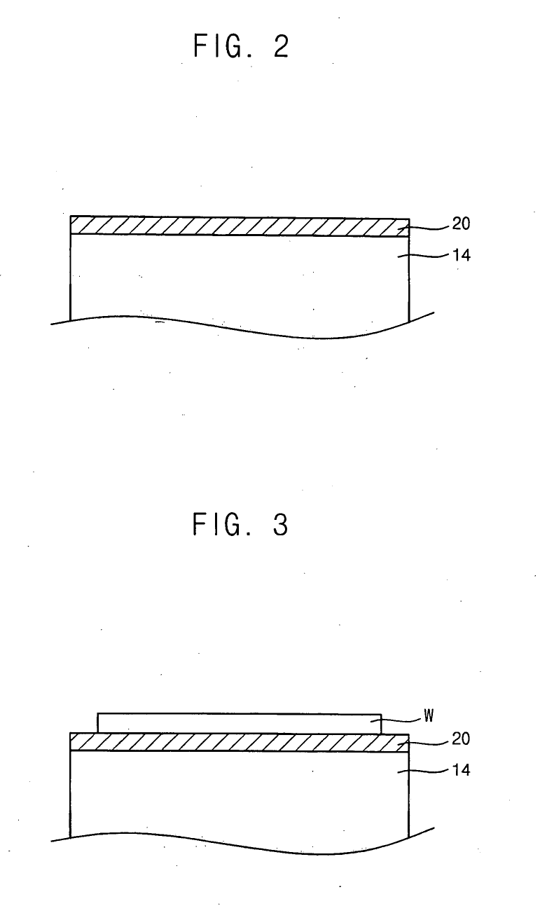

FIG. 2 is a sectional diagram illustrating the formation of a thin film on the chuck of the apparatus of FIG. 1 after a plasma gas is established within the apparatus, according to some embodiments of the invention.

Referring to FIGS. 1 and 2, a process gas for processing a semiconductor substrate W is introduced into the chamber 10. Furthermore, the source power and the bias power are applied to the chamber 10 to form a plasma gas in the chamber 10. After the plasma gas is formed in the chamber 10, a thin layer 20 is formed on the chuck 14.

FIG. 3 is a sectional diagram illustrating the positioning of a semiconductor substrate on the chuck of the apparatus of FIG. 1 after the thin film is formed.

Referring to FIGS. 1 and 3, the semiconductor substrate W is loaded into the chamber 10. The semiconductor substrate W is placed on the thin layer 20 that was formed on the chuck 14. The semiconductor substrate W is then processed using the plasma gas.

After the processing of the semiconductor substrate W is completed, the semiconductor substrate W is unloaded from the chamber 10. Next, a cleaning gas is introduced into the chamber 10 to remove byproducts on an inner wall of the chamber 10 that are generated during the processing the semiconductor substrate W. In particular, the cleaning gas is converted into a plasma gas in the chamber 10. The plasma gas reacts with the byproducts, detaching the byproducts from the inner wall of the chamber 10.

Next, a purge gas is introduced into the chamber 10 to exhaust the detached byproducts, contaminants, and remaining gases from the chamber 10. Exemplary purge gases may include an argon gas or a nitrogen gas, which may be used either alone or in combination.

As described above, forming the process atmosphere, loading the semiconductor substrate W, processing the semiconductor substrate W, unloading the semiconductor substrate, removing the byproducts, and purging the byproducts, contaminants and the remaining gases are sequentially carried out to complete the processing of the semiconductor substrate W.

However, the applicants noticed that during the processing of the semiconductor substrate W, the semiconductor substrate W moved frequently on the chuck 14. As was explained above, movement of the semiconductor substrate W is undesirable.

Initially, the movement of the semiconductor substrate W was assumed to be caused by the chuck 14. Thus, the chuck 14 was exchanged for a new one. However, the semiconductor substrate W still moved frequently during processing, despite the exchange of the chuck 14.

Next, it was assumed that the movement of the semiconductor substrate W during processing was due to the presence of the byproducts within the chamber. Thus, the process for removing the byproducts was performed several times for a relatively long time. In particular, the process for removing the byproducts was performed until the thin layer 20 on the chuck 14 was completely removed. However, in spite of the removal of the thin layer 20 from the chuck 14, the semiconductor substrate W still moved during processing.

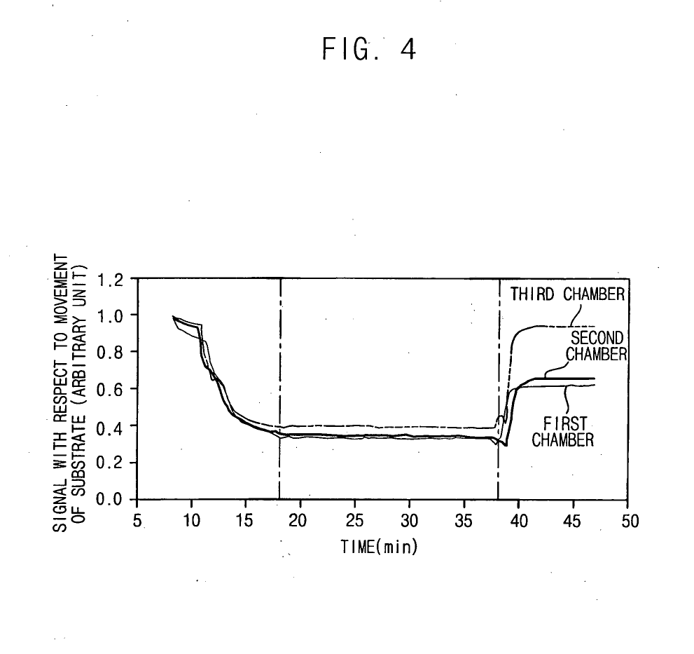

FIG. 4 is a graph illustrating characteristics of fluorine in accordance with process conditions for removing byproducts in the process using the plasma gas. In FIG. 4, a horizontal axis represents time, and a vertical axis represents a normalized signal (arbitrary unit) with respect to the semiconductor substrate. Further, a period between dotted lines in FIG. 4 corresponds to a main coating process.

In particular, a silicon oxide layer as the thin layer 20 was formed on the chuck 14 by forming the process atmosphere. The silicon oxide layer was removed using an NF3 gas as the cleaning gas. The process for removing the byproducts was carried out once on first and second chambers, respectively. The process for removing the byproducts was carried out three times on a third chamber. It should be noted that the semiconductor substrate W in the third chamber was more moved compared to those in the first and second chambers. Further, amounts of fluorine in the first, second and third chambers were measured at a peak of 703 nm, which corresponded to a peculiar peak of fluorine, using an optical emission spectroscopy (OES). It should be noted that fluorine in the third chamber had an amount greater than each amount of fluorine in the first and second chambers.

Furthermore, the semiconductor substrate W was processed without removing the byproducts. It should be noted that the semiconductor substrate W was almost not moved.

Thus, the applicants concluded that the amount of movement of the semiconductor substrate W was related to the time and the cycle of the process for removing the byproducts. The applicants performed additional tests based upon the above results.

In the additional tests, the process atmosphere was provided to the chamber 10 to form a silicon oxide layer 20 on the chuck 14 of the apparatus 100. Byproducts were then removed according to two different conditions, which will be referred to as a first condition and a second condition.

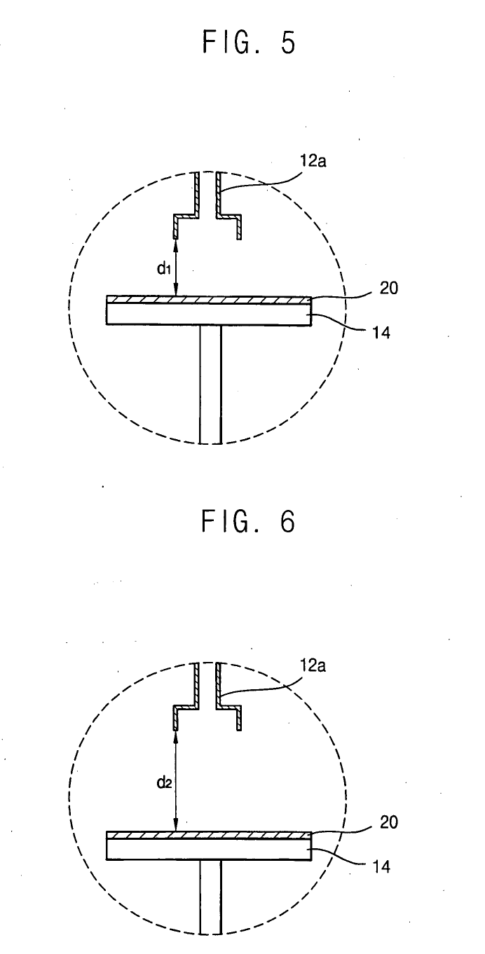

FIG. 5 is a sectional diagram illustrating a method of removing byproducts under the first condition in accordance with some embodiments of the invention. The first condition, as shown in FIG. 5, is that a first distance d1 is provided between an inlet of the first gas line 12a and the chuck 14. Here, the first distance d1 was approximately 10 cm.

FIG. 6 is a sectional diagram illustrating a method of removing byproducts under a second condition in accordance with some embodiments of the invention. The second condition, as shown in FIG. 6, is that a second distance d2 is provided between an inlet of the first gas line 12a and the chuck 14. Here, the second distance d2 was approximately 12 cm. The distance d1 or d2 may be set by adjusting the height of the chuck 14 in the apparatus 100. For both the first condition and the second condition, an NF₃ gas was used in the process for removing the byproducts.

Under the first condition, the silicon oxide layer 20 on the chuck 14 was removed at an etching rate of about 2,330 Å/min. On the other hand, under the second condition the silicon oxide layer 20 on the chuck 14 was removed at an etching rate of about 1,890 Å/min.

Based on the above results, the applicants noted that the etching rate of the silicon oxide layer 20 was proportional to the distance between the first gas line 12a and the chuck 14. In other words, as the concentration of gas decreases as the distance between the first gas line 12a and the chuck 14 increases, the etching rate of the silicon oxide layer 20 decreases. Thus, the etching rate of the silicon oxide layer 20 was proportional to the concentration of the NF₃ gas for removing the byproducts.

Therefore, according to some embodiments of the invention, during the process for forming a thin layer on the semiconductor substrate W, the distance between the inlet of the first gas line 12a and the chuck 14 is preferably equal to a first distance d1. During the process for removing the byproducts, the distance between the inlet of the first gas line 12a and the chuck 14 is preferably equal to a second distance d2, where d2 is greater than d1.

In the illustrated embodiments, although the distance between the first gas line 12a and the chuck 14 is the distance that is adjusted to achieve different etching rates, in alternative embodiments the distance between the second gas line 12b and the chuck 14 could be adjusted to achieve the same effect.

According to the illustrated embodiments of the invention, the plasma gas for removing the byproducts under the second condition has a reactivity with respect to the chuck 14 that is smaller than that of the plasma gas under the first condition. That is, when the second distance d2 is provided between the first gas line 12a and the chuck 14, the reactivity of the plasma gas with respect to the chuck 14 is reduced compared to the reactivity when the first distance d1 is provided between the first gas line 12a and the chuck 14. The second distance d2 is longer than the first distance d1. In the illustrated embodiments, the second distance d2 is preferably about 1.1 to about 5.0 times the first distance d1. For example, when the first distance d1 is about 10 cm, the second distance d2 is about 11 cm to about 50 cm.

The adjustment of the second distance d2 may be accomplished by moving the chuck 14 or the first and second gas lines 12a and 12b. When the chamber 10 is configured so that gas flows in a downward direction, the chuck 14, the first gas line 12a, and the second gas line 12b may be moved in a vertical direction to achieve the desired distance d2. It should be recognized that the desired distance d2 can be achieved by moving only one of the chuck 14 and gas lines 12a, 12b, or that both the chuck 14 and one of the gas lines 12a, 12b could be moved.

According to the illustrated embodiments, the semiconductor substrate W is processed under the first condition such that a first distance d1 is provided between the first and second gas lines 12a and 12b and the chuck 14. Furthermore, the byproducts are removed under the second condition such that a second distance d2 (d2>d1) is provided between the first and second gas lines 12a and 12b and the chuck 14. Preferably, the second distance d2 is about 1.1 to about 5.0 times the distance of d1. Thus, the plasma gas as a cleaning material under the second condition has a reactivity that is smaller than the plasma gas under the first condition. As a result, when the semiconductor substrate W is processed, the semiconductor substrate W may remain stable on the chuck 14, without movement.

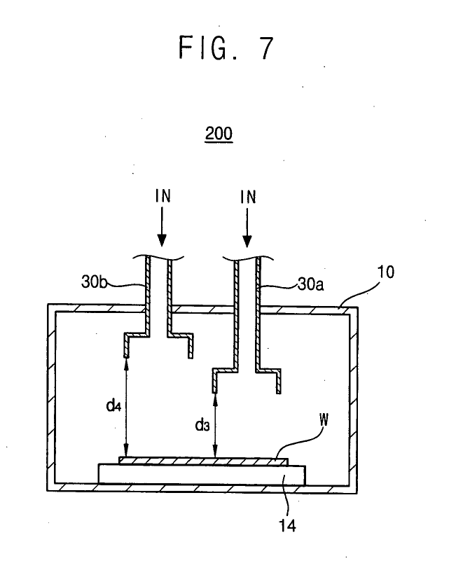

FIG. 7 is a sectional diagram illustrating an apparatus that is capable of performing a process using a plasma gas in accordance with some other embodiments of the invention.

Referring to FIG. 7, the apparatus 200 includes elements that are substantially the same as those illustrated in FIG. 1, except for the gas lines. Thus, reference numerals in FIG. 7 that are the same as the reference numerals in FIG. 1 refer to the same elements and an unnecessarily duplicative description of those elements is omitted.

Referring to FIG. 7, the apparatus 200 includes a chamber 10, a chuck 14 in the chamber 10 for supporting a semiconductor substrate W, and first and second gas lines 30a and 30b. The first and second gas lines 30a and 30b are connected to an upper face of the chamber 10.

A third distance d3 is provided between an inlet of the third gas line 30a and the chuck 14. Furthermore, a fourth distance d4 is provided between an inlet of the fourth gas line 30b and the chuck 14. The fourth distance d4 is longer than the third distance d3. In the illustrated embodiments, the fourth distance d4 is preferably about 1.1 to about 5.0 times the third distance d3. For example, when the third distance d3 is about 10 cm, the fourth distance d4 is about 11 cm to about 50 cm.

A method of manufacturing a semiconductor device in accordance with the illustrated embodiments using the apparatus 200 is described in the paragraphs below.

A process atmosphere is provided to the chamber 10. The semiconductor substrate W is placed on the thin layer 20 of the chuck 14. A gas provided from the first gas line 30a is converted into a first plasma gas. The semiconductor substrate W is processed using the first plasma gas. The semiconductor substrate W is then unloaded from the chamber 10.

A gas provided from the second gas line 30b is converted into a second plasma gas. Byproducts in the chamber 10 are removed using the second plasma gas. A purge gas is introduced into the chamber 10 to exhaust the byproducts, contaminants, and remaining gases from the chamber 10.

In the illustrated embodiments, processing the semiconductor substrate W is carried out using the first plasma gas that is generated from the gas through the first gas line 30a. In addition, removing the byproducts is carried out using the second plasma gas that is generated from the gas through the second gas line 30b. Processing the semiconductor substrate W may include a deposition process for forming a thin layer on the semiconductor substrate W or an etching process for patterning the thin layer on the semiconductor substrate W.

According to the illustrated embodiments, the semiconductor substrate W is stably positioned on the chuck 14 while it is processed. In other words, the movement of the semiconductor substrate W during processing is reduced.

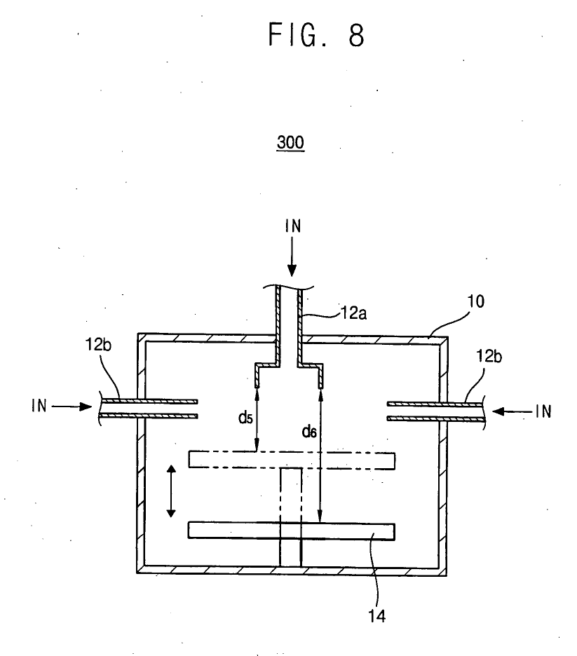

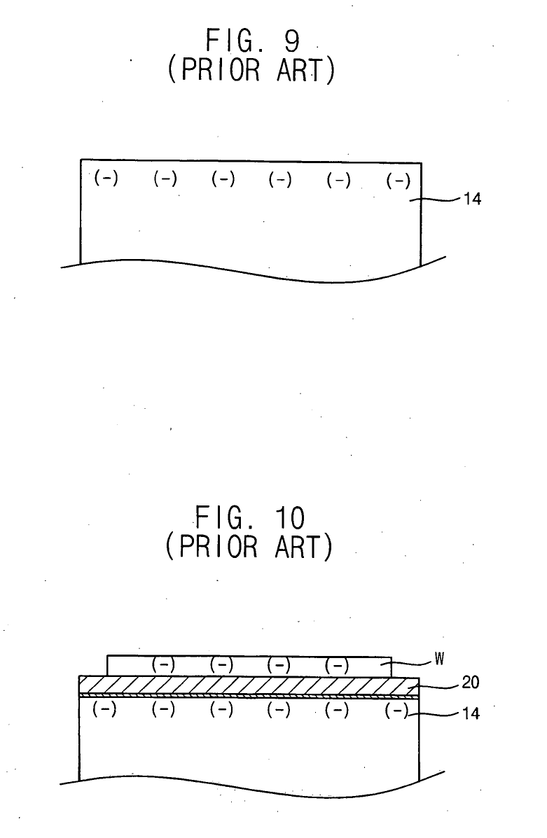

FIG. 8 is a sectional diagram illustrating an apparatus capable of performing a process using a plasma gas in accordance with some other embodiments of the invention. FIGS. 9 and 10 are sectional diagrams illustrating a process in accordance with some other embodiments of the invention, which uses the apparatus of FIG. 8.

Referring to FIG. 8, the apparatus 300 includes elements that are substantially the same as those illustrated in FIG. 1. Thus, reference numerals in FIG. 7 that are the same as the reference numerals in FIG. 1 refer to the same elements and an unnecessarily duplicative description of those elements is omitted.

A silicon oxide layer is formed on the semiconductor substrate W on the chuck 14 in the chamber 10 using a first plasma gas. The semiconductor substrate W is then unloaded from the chamber 10. In particular, the process for forming the silicon oxide layer is carried out under a first condition that a fifth distance d5 is provided between the first and second gas lines 12a and 12b for providing the chamber 10 with a gas and the chuck 14. Exemplary gases include a SiH₄ gas or an O₂ gas.

After the silicon oxide layer is formed, byproducts are attached to an inner wall of the chamber 10. The byproducts are removed using a second plasma gas that is generated from a gas provided through the first and second gas lines 12a and 12b. The process for removing the byproducts is carried out under a second condition that a sixth distance d6 is provided between the first and second gas lines 12a and 12b and the chuck 14. The sixth distance d6 is longer than the fifth distance d5.

The second plasma gas for removing the byproducts under the second condition has a cleaning ability that is smaller than that of the second plasma gas under the first condition. That is, when the sixth distance d6 is provided between the first gas line 12a and the chuck 14, the cleaning force of the plasma gas is reduced compared to the cleaning ability when the fifth distance d5 is provided between the first gas line 12a and the chuck 14.

In the illustrated embodiments, the chuck 14 is downwardly moved to provide the sixth distance d6 between the first gas line 12a and the chuck 14. Furthermore, although FIG. 8 illustrates an adjustment of the distance between the first gas line 12a and the chuck 14, adjustment of a distance between the second gas line 12b and the chuck 14 is substantially the same and would be apparent to one of skill in the art.

After the sixth distance d6 is provided between the first and second gas lines 12a and 12b and the chuck 14, a gas for removing the byproducts is introduced into the chamber 10 through the first and second gas lines 12a and 12b. Since the byproducts include silicon oxide, the gas may include, for example, a halogen compound or combinations of different halogen compounds. Examples of halogen compounds include, for example, C₃F₈, NF₃, F₂, Cl₂, ClF₃, HBr, and Br₂.

A source power and a bias power are applied to the chamber 10 once the gas has been introduced to generate the second plasma gas. The byproducts are then removed using the second plasma gas. Here, a material such as fluorine may be chemisorbed or physisorbed on the chuck 14. However, according to the illustrated embodiments, since the process for removing the byproducts is carried out under the second condition that the sixth distance d6 is provided between the first and second gas lines 12a and 12b and the chuck 14, the amount of material such as fluorine that is chemisorbed or physisorbed on the chuck 14 may be remarkably reduced.

After the byproducts are removed, a purge gas is introduced into the chamber 10 to exhaust the remaining byproducts and second plasma gas from the chamber 10.

The chuck 14 is upwardly moved to provide the fifth distance d5 between the first and second gas lines 12a and 12b and the chuck 14. The silane gas and the oxygen gas are introduced into the chamber 10. Furthermore, a source power and a bias power are applied to the chamber 10 to form a process atmosphere, thereby forming a thin layer 20 on the chuck 14. As a result, as shown in FIG. 10, a material such as fluorine exists between the chuck 14 and the thin layer 20.

The semiconductor substrate W is loaded into the chamber 10. The semiconductor substrate W is placed on the chuck 14. A process for forming a silicon oxide layer on the semiconductor substrate W is carried out.

According to the conventional art, when the process for forming the silicon oxide layer is performed, the semiconductor substrate is charged with electric charges of particles colliding against the semiconductor substrate W. Thus, the semiconductor substrate W is charged with negative charges. In addition, since the chuck 14 is charged with negative charges due to fluorine, a repulsive force is generated between the chuck 14 and the semiconductor substrate W. Thus, the semiconductor substrate W on the chuck 14 may be minutely moved due to the repulsive force.

To the contrary, in the illustrated embodiments, since the byproducts are removed under the second condition that the sixth distance d6 is provided between the first and second gas lines 12a and 12b and the chuck 14, the material such as fluorine may not be chemisorbed or physisorbed on the chuck 14. Thus, the semiconductor substrate W on the chuck 14 may not be moved in forming the silicon oxide layer using the plasma gas.

According to the illustrated embodiments, the silicon oxide layer is formed on the semiconductor substrate W under the first condition that the fifth distance d5 is provided between the first and second gas lines 12a and 12b and the chuck 14. Furthermore, the byproducts are removed under the second condition that the sixth distance d6 is provided between the first and second gas lines 12a and 12b and the chuck 14. Thus, the semiconductor substrate W on the chuck 14 will not be moved during formation of the silicon oxide layer.

According to embodiments of the invention, a distance between the line and the chuck during processing of the semiconductor substrate is different from the distance between the line and the chuck during removal of the byproducts. Thus, a material having a high electronegativity does not attach to the chuck and a semiconductor substrate placed on the chuck is not moved.

As a result, the semiconductor substrate may be stably processed and the resulting semiconductor device may have improved reliability and productivity.

The invention may be practiced in many ways. What follows are exemplary, non-limiting descriptions of some embodiments of the invention.

A method of manufacturing a semiconductor device according to some embodiments of the invention includes providing a first distance between a gas line configured to introduce gas into a processing chamber and a chuck configured to support a substrate within the processing chamber. A first material is applied to the substrate through the gas line in order to process the substrate. The method further includes providing a second distance between the gas line and the chuck. A second material is then introduced into the processing chamber through the gas line, and byproducts generated during processing of the substrate are removed using a second material. At the second distance, the second material has a reactivity with respect to the chuck that is smaller than the reactivity at the first distance.

A method of manufacturing a semiconductor device according to some other embodiments of the invention includes providing a first distance between a first gas line for providing a first material and a chuck for supporting a substrate. The method further includes providing a second distance between a second gas line for providing a second material and the chuck. At the second distance, the second material has a reactivity with respect to the chuck that is smaller than the reactivity at the first distance. The first material is applied to the substrate on the chuck through the first line in order to process the substrate. Byproducts generated during the processing of the substrate are then removed using the second material.

A method of manufacturing a thin layer of a semiconductor device according to still other embodiments of the invention includes providing a first distance between a gas line inlet for providing a chamber with process materials and a chuck for supporting a substrate. A deposition material is applied to the substrate on the chuck through the gas line inlet to form the thin layer on the substrate. The method further includes providing a second distance between the gas line inlet and the chuck. Byproducts generated during the processing of the substrate are then removed using a cleaning material. At the second distance, the cleaning material has a cleaning ability with respect to the chuck that is smaller than the cleaning ability at the first distance.

According to embodiments of the invention, when a substrate is being processed using a plasma gas, a distance between the chuck and the inlet of a gas line may be adjusted so that the substrate on the chuck does not move while it is being processed.

Having described several preferred embodiments of the invention, it is apparent that various modifications and variations could be made by persons skilled in the art without departing from the teachings of the invention. It is therefore to be understood that changes may be made to the disclosed embodiments that nevertheless fall within the scope of the invention as defined by the attached claims.

1. A method of manufacturing a semiconductor device, the method comprising:
arranging a relative position between a gas line inlet disposed in a processing chamber and a chuck configured to support a substrate within the processing chamber such that a first distance separates the gas line inlet and the chuck;
processing the substrate using a first material that is provided to the processing chamber through the gas line inlet while the gas line inlet and the chuck are separated by the first distance;
arranging the relative position between the gas line inlet and the chuck such that a second distance separates the gas line inlet and the chuck; and
removing byproducts generated during the processing using a second material that is provided to the processing chamber through the gas line inlet while the gas line inlet and the chuck are separated by the second distance, the second material having a reduced reactivity with respect to the chuck when the gas line inlet and the chuck are separated by the second distance then when the gas line inlet and the chuck are separated by the first distance.

2. The method of claim 1, wherein processing the substrate comprises one selected from the group consisting of a deposition process for forming a thin layer on the substrate and an etching process for patterning the thin layer on the substrate.

3. The method of claim 1, the first material comprising a plasma gas.

4. The method of claim 1, wherein arranging the relative position between the gas line inlet and the chuck comprises one selected from the group consisting of moving the chuck, moving gas line inlet, and moving both the chuck and the gas line inlet.

5. The method of claim 1, the second distance greater than the first distance.

6. The method of claim 5, the second distance about 1.1 to about 5.0 times greater than the first distance.

7. The method of claim 1, the second material comprising a plasma gas.

8. The method of claim 1, further comprising, prior to arranging the relative position between the gas line inlet and the chuck such that the second distance separates the gas line inlet and the chuck, unloading the substrate from the processing chamber.

9. The method of claim 1, further comprising, after removing byproducts, purging the processing chamber with a purge gas provided through the gas line inlet.

10. A method of manufacturing a semiconductor device, the method comprising:
setting a first gas line configured to provide a first material to a processing chamber at a first distance away from a chuck configured to support a substrate within the processing chamber;
setting a second gas line configured to provide a second material to the processing chamber at a second distance away from the chuck;
processing the substrate using the first material; and
removing byproducts generated during processing using the second material.

11. The method of claim 10, wherein the second distance is greater than the first distance.

12. The method of claim 10, wherein processing the substrate comprises one selected from the group consisting of a deposition process for forming a thin layer on the substrate and an etching process for patterning the thin layer on the substrate.

13. The method of claim 10, the first and second materials comprising a plasma gas.

14. The method of claim 10, further comprising:
before processing the substrate, providing the first material to the processing chamber using the first gas line to form a process atmosphere;
after processing the substrate, unloading the substrate from the processing chamber; and
after removing the byproducts, providing purge gas to the processing chamber.

15. A method comprising:
arranging a gas line inlet for supplying a processing chamber with processing materials and a chuck for supporting a substrate within the processing chamber such that they are a first distance apart;
supplying the processing chamber with a deposition material through the gas line inlet to form a thin layer on the substrate;
arranging the gas line inlet and the chuck such that they are a second distance apart; and
supplying the processing chamber with a cleaning material through the gas line inlet to remove byproducts generated when the thin layer was formed on the substrate, the cleaning material having a reduced cleaning ability with respect to the chuck when the gas line inlet and the chuck are disposed the second distance compared to when the gas line inlet and the chuck are disposed the first distance apart.

16. The method of claim 15, wherein the deposition material comprises a plasma gas containing silane and oxygen.

17. The method of claim 15, wherein the second distance is longer than the first distance, and providing the second distance comprises moving the chuck and/or the line.

18. The method of claim 15, wherein the cleaning material comprises a plasma gas containing a halogen compound.

19. The method of claim 18, wherein the halogen compound is one selected from the group consisting of C₃F₈, NF₃, F₂, Cl₂, ClF₃, HBr, and Br₂.

20. The method of claim 15, further comprising:
providing the chamber with the deposition material to form a process atmosphere, before forming the thin layer;
unloading the substrate from the chamber, after forming the thin layer; and
providing the chamber with a purge gas, after removing the byproducts.
